(19) United States
(12) Patent Application Publication
(10) Pub. No.: US 2018/0371623 A1
(43) Pub. Date: Dec. 27, 2018

(54) METHOD FOR SMOOTHING SURFACE ROUGHNESS OF COMPONENTS

(71) Applicant: Hamilton Sundstrand Corporation, Charlotte, NC (US)

(72) Inventors: Gary M. Lomasney, Glastonbury, CT (US); Robert Bianco, Columbia Station, OH (US); Mark R. Jaworowski, Glastonbury, CT (US); Sergey Mironets, Charlotte, NC (US)

(21) Appl. No.: 15/631,803

(22) Filed: Jun. 23, 2017

(51) Int. Cl. C23C 24/10; C23C 4/18; C23C 4/02; C23C 14/18; B44C 1/20

(52) U.S. Cl. CPC C23C 24/10; C23C 4/18; C23C 4/02; B33Y 10/00; B44C 1/205; F05B 2250/62; C23C 14/18

(57) ABSTRACT

A method for reducing surface roughness of a component according to an example of the present disclosure includes forming a layer of reactive material on a surface of a component, the surface of the component having at least one partially attached particle, whereby the reactive material substantially covers the at least one partially attached particle, and dissolving the reactive material, wherein dissolving the reactive material covering the partially attached particles causes the partially attached particles to break free from the surface of the component, leaving a new smooth surface.

Another method for reducing surface roughness of an engine component according to an example of the present disclosure includes forming a component by additive manufacturing, the component including an internal feature having at least one rough area, the rough area including at least one partially attached particle, forming an aluminum layer on the surface of the component, the aluminum layer substantially covering the at least one partially attached particle, heat treating the component to cause diffusion of aluminum in a diffusion zone, and dissolving away the aluminum layer and diffusion zone, wherein dissolving the aluminum covering the at least one partially attached particle and the diffusion zone causes the at least one partially attached particle to be freed from the surface of the component.

### BACKGROUND

This disclosure relates to a method of reducing the surface roughness.

Additively manufactured components often include excessive surface roughness from satellite particles or surface asperities that occurring from incomplete consolidation at the component surface. Satellite particles can detach and cause damage to other surrounding components. Smoothing of such roughnesses can be difficult, especially in internal passages, blind holes, or other non-line-of-sight surfaces.

### SUMMARY

A method for reducing surface roughness of a component according to an example of the present disclosure includes forming a layer of reactive material on a surface of a component, the surface of the component having at least one partially attached particle, whereby the reactive material substantially covers the at least one partially attached particle, and dissolving the reactive material, wherein dissolving the reactive material covering the partially attached particles causes the partially attached particles to break free from the surface of the component, leaving a new smooth surface.

In a further embodiment of the foregoing embodiment, the component includes an internal feature, and the internal feature includes a non-line-of-sight surface.

In a further embodiment of any of the foregoing embodiments, the at least one partially attached particle is on the non-line-of-sight surface.

A further embodiment of any of the foregoing embodiments includes conveying a solution through the internal features during the dissolving step. The solution dissolves the reactive material.

In a further embodiment of any of the foregoing embodiments, the solution is inert with respect to the component.

In a further embodiment of any of the foregoing embodiments, the reactive material is an element selected from one of aluminum, bromine, silicon, chromium, zinc, tin, titanium, yttrium, or any combination thereof.

In a further embodiment of any of the foregoing embodiments, the reactive material is aluminum and the component comprises a nickel alloy.

A further embodiment of any of the foregoing embodiments includes forming the component by additive manufacturing. The at least one partially attached particle is one of a partially melted particle and a partially sintered particle.

A further embodiment of any of the foregoing embodiments includes heat treating the component to cause diffusion of the reactive material into a diffusion zone.

In a further embodiment of any of the foregoing embodiments, the dissolving step dissolves away the layer of reactive material and the diffusion zone.

In a further embodiment of any of the foregoing embodiments, forming the layer of reactive material is accomplished by a gas phase deposition process.

In a further embodiment of any of the foregoing embodiments, the gas phase deposition process including flowing gas containing the reactive material in a laminar flow.

In a further embodiment of any of the foregoing embodiments, the dissolving step is accomplished with an acidic solution.

In a further embodiment of any of the foregoing embodiments, the acidic solution is a 20%-50% solution of nitric acid. The dissolving step is performed at a temperature of between about 90 and 100° F. (32.2 and 37.8° C.).

A method for reducing surface roughness of an engine component according to an example of the present disclosure includes forming a component by additive manufacturing, the component including an internal feature having at least one rough area, the rough area including at least one partially attached particle, forming an aluminum layer on the surface of the component, the aluminum layer substantially covering the at least one partially attached particle, heat treating the component to cause diffusion of aluminum in a diffusion zone, and dissolving away the aluminum layer and diffusion zone, wherein dissolving the aluminum covering the at least one partially attached particle and the diffusion zone causes the at least one partially attached particle to be freed from the surface of the component.

In a further embodiment of any of the foregoing embodiments, the component is a nickel alloy component.

In a further embodiment of any of the foregoing embodiments, forming the aluminum layer is accomplished by a gas phase deposition process.

A further embodiment of any of the foregoing embodiments includes conveying a solution through the internal features during the dissolving step, wherein the solution dissolves the aluminum.

In a further embodiment of any of the foregoing embodiments, the solution does not react with the component.

In a further embodiment of any of the foregoing embodiments, the solution is a 20%-50% solution of nitric acid, and wherein the dissolving step is performed at a temperature of between about 90 and 100° F. (32.2 and 37.8° C.).

### BRIEF DESCRIPTION OF THE DRAWINGS

FIG. 1 schematically shows a component with rough areas.

FIG. 2 schematically shows a method of smoothing the component.

FIG. 3 schematically shows a surface of the component with a reactive layer.

### DETAILED DESCRIPTION

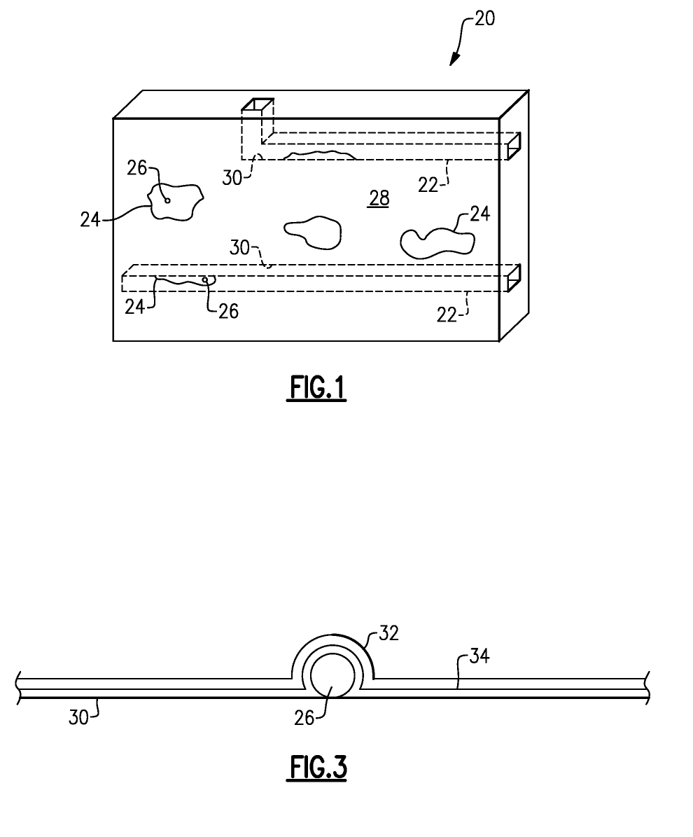

FIG. 1 is a schematic view of an example component 20 with internal features 22. As an example, the component 20 is a heat exchanger and the internal features 22 are cooling passages, lattice structures, blind holes, or the like. However, the component 20 can alternatively be any type of gas turbine engine component, such a fuel nozzle, airfoil, combustor liner, another hollow part, or even a non-engine component.

The component 20 is formed by an additive manufacturing process, such as a powder-bed fusion process. This process creates rough areas or surfaces 24. For instance, the additive manufacturing process results in partially melted and solidified powder at the interface of a powder bed and a laser beam during the power-bed fusion process. This partially melted and solidified powder forms rough surfaces or areas 24. In another example, rough surfaces or areas 24 include partially sintered areas. This disclosure is not limited to components produced by additive manufacturing and other processes that produce rough surfaces may also benefit. The rough areas 24 can be on an outer surface 28 of the component 20 or on non-line-of-sight surfaces 30 of the internal features 22, which are particularly challenging to access. In one example, some of the rough areas 24 include particles 26 that are partially attached to the component 20, known as “satellite particles.” In one example, the satellite attached particles 26 are partially melted particles or partially sintered particles left behind during additive manufacturing of component 20, as discussed above.

In the case where the component 20 is a heat exchanger and internal features 22 are cooling passages, satellite particles 26 can be liberated from the heat exchanger 20 during operation and can damage other parts of the heat exchanger 20 and/or other adjacent components. Also, rough areas 24 within cooling passages 22 cause excessive pressure drop of fluid flowing through the cooling passages 22, which reduces the cooling efficiency of the heat exchanger 20 and reduces the fatigue life of the heat exchanger 20.

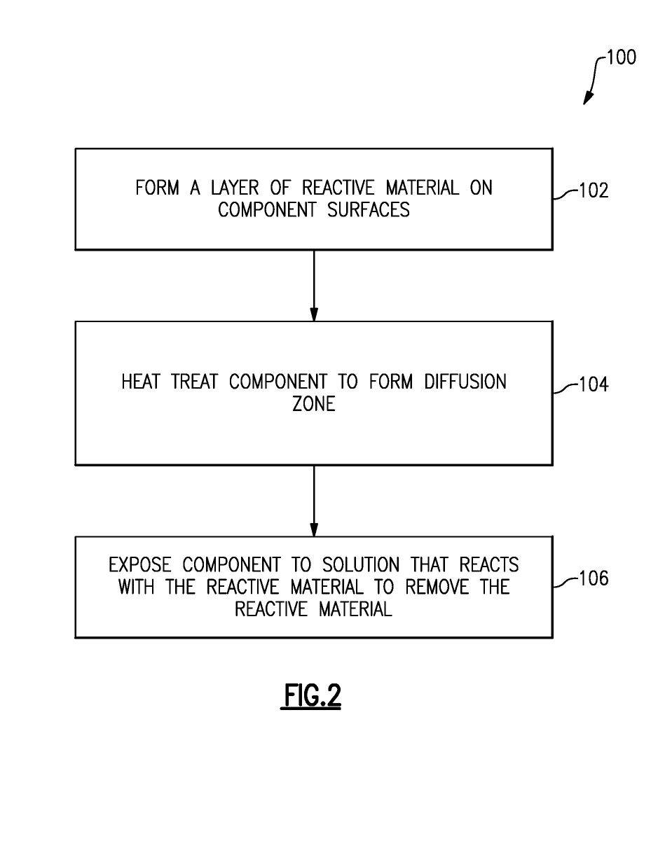

FIG. 2 shows a method 100 of smoothing the rough areas 24 of the component 20. In step 102, a layer 32 of reactive material is formed on the rough areas 24 of the component 20. FIG. 3 shows a layer 32 of reactive material on a non-line-of-sight surface 30 with a satellite particle 26. The reactive material is more reactive than the material of the component 20. That is, a reaction can be induced with the reactive material but not with the material of the component 20, it least to a substantially lesser extent. This enables the reactive material to be removed without disturbing or affecting the material of the component 20, as will be discussed further below. In one example, the dissolution rate of the reactive material is at least ten times greater than the dissolution rate of the material of the component 20. In a further example, the dissolution rate of the reactive material is 100 times greater than the dissolution rate of the material of the component 20.

For example, the component 20 discussed herein is a nickel alloy, which is relatively inert, and the reactive material is aluminum. However, it should be understood that other component 20 materials and reactive materials can be used. For instance, the reactive material can include any of aluminum, bromine, silicon, chromium, zinc, tin, titanium, yttrium, any combination thereof, or another reactive element.

The aluminum is applied to the component 20 by a gas phase deposition process, such as Chemical Vapor Deposition (“CVD”), to form the reactive layer 32. In a particular example, the aluminum is applied by chlorine-catalyzed CVD of aluminum vapor. Gas phase deposition processes typically involve flowing gas with a material to be deposited (in this example, aluminum) into a chamber containing the component 20. In one example, the gas flow is laminar. For instance, the Reynolds number is less than about 2300 Laminar flow allows for more concentrated deposition of aluminum on high points (such as rough areas 24 and satellite particles 26) of the surfaces 28, 30 of the component 20. This in turn ensures the satellite particles 26 are substantially covered by the reactive material.

Referring again to FIG. 2, in step 104, the component 20 with the reactive layer 32 is heat treated. Heat treatment can be performed by any known method, and the parameters of the heat treatment will depend on the material of the component 20 and the reactive layer 32. The heat treatment causes diffusion of the component 20 material and the reactive layer 32 material into a diffusion zone 34 (FIG. 3). In the present example, the diffusion zone 34 contains a mixture of nickel and aluminum. Importantly, the reactive layer 32 and diffusion zone 34 are present over the satellite particles 26.

In step 106, component 20 is exposed to a solution that reacts with the reactive material in the reactive layer 32 and the diffusion zone 34 to remove the reactive layer 32 and the diffusion zone 34. In one example, the solution is an acidic solution, such as a nitric acid solution. More particularly, the solution is a 20%-50% nitric acid solution. The solution reacts with the aluminum whereby aluminum-rich areas of the component 20 are dissolved away, including the diffusion zone 34 and the reactive layer 32.

As discussed above, the satellite particles 26 are only partially attached to the surfaces 28, 30 of the component 20. In this dissolving process, the satellite particles 26 are substantially covered by the reactive layer 32 and diffusion zone 34. As the reactive layer 32 and diffusion zone 34 are dissolved away, the satellite particles 26 break free from the surface 28, 30 of the component to expose a new smoother surface. The freed particles 26 are carried away by the solution. This is especially effective if good coverage of the satellite particles 26 is achieved by laminar flow CVD, as discussed above. This results in smoothing of rough areas 24. Exposure to the solution can include flowing the solution through the internal features 22 of the component 20. This allows the dissolving process and satellite particle removal 26 to occur on non-line-of-sight surfaces 30. The removal step does not affect the underlying nickel alloy of the component 20 because the nickel alloy is inert with respect to the solution, or at least substantially less reactive than the aluminum.

In one example, during step 106, the component 20 is exposed to the solution at an elevated temperature. More particularly, the exposure occurs at about 90-100° F. (32.2-37.8° C.).

The method discussed above results in smoothing of outer surfaces 28 and non-line-of-sight surfaces 30 of the component 20 without damaging or altering the material of the component 20, which improves the service life as well as tensile and fatigue properties of the component 20. Furthermore, the method can be used to smooth non-line-of-sight surfaces 30, which are difficult to smooth by other methods (such as electrochemical methods or employing abrasive media), particularly where the internal features 22 have complex or convoluted shapes. This in turn results in time and costs savings for manufacturing components with internal features.

Furthermore, the foregoing description shall be interpreted as illustrative and not in any limiting sense. A worker of ordinary skill in the art would understand that certain modifications could come within the scope of this disclosure. For these reasons, the following claims should be studied to determine the true scope and content of this disclosure.

1. A method for reducing surface roughness of a component, comprising:
forming a layer of reactive material on a surface of a component, the surface of the component having at least one partially attached particle, whereby the reactive material substantially covers the at least one partially attached particle;
dissolving the reactive material, wherein dissolving the reactive material covering the partially attached particles causes the partially attached particles to break free from the surface of the component, leaving a new smooth surface; and
forming the component by additive manufacturing, wherein the at least one partially attached particle is one of a partially melted particle and a partially sintered particle.

2. The method of claim 1, wherein the component includes an internal feature, and the internal feature includes a non-line-of-sight surface.

3. The method of claim 2, wherein the at least one partially attached particle is on the non-line-of-sight surface.

4. The method of claim 3, further comprising conveying a solution through the internal features during the dissolving step, the solution dissolving the reactive material.

5. The method of claim 4, wherein the solution is inert with respect to the component.

6. The method of claim 1, wherein the reactive material is an element selected from one of aluminum, bromine, silicon, chromium, zinc, tin, titanium, yttrium, or any combination thereof.

7. The method of claim 6, wherein the reactive material is aluminum and the component comprises a nickel alloy.

8. (canceled)

9. The method of claim 1, further comprising heat treating the component to cause diffusion of the reactive material into a diffusion zone.

10. The method of claim 9, wherein the dissolving step dissolves away the layer of reactive material and the diffusion zone.

11. The method of claim 1, wherein forming the layer of reactive material is accomplished by a gas phase deposition process.

12. The method of claim 11, wherein the gas phase deposition process including flowing gas containing the reactive material in a laminar flow.

13. The method of claim 1, wherein the dissolving step is accomplished with an acidic solution.

14. The method of claim 13, wherein the acidic solution is a 20%-50% solution of nitric acid, and wherein the dissolving step is performed at a temperature of between about 90 and 100° F. (32.2 and 37.8° C.).

15. A method for reducing surface roughness of an engine component, comprising:
forming a component by additive manufacturing, the component including an internal feature having at least one rough area, the rough area including at least one partially attached particle;
forming an aluminum layer on the surface of the component, the aluminum layer substantially covering the at least one partially attached particle;
heat treating the component to cause diffusion of aluminum in a diffusion zone; and
dissolving away the aluminum layer and diffusion zone, wherein dissolving the aluminum covering the at least one partially attached particle and the diffusion zone causes the at least one partially attached particle to be freed from the surface of the component.

16. The method of claim 15, wherein the component is a nickel alloy component.

17. The method of claim 15, wherein forming the aluminum layer is accomplished by a gas phase deposition process.

18. The method of claim 15, further comprising conveying a solution through the internal features during the dissolving step, wherein the solution dissolves the aluminum.

19. The method of claim 18, wherein the solution does not react with the component.

20. The method of claim 18, wherein the solution is a 20%-50% solution of nitric acid, and wherein the dissolving step is performed at a temperature of between about 90 and 100° F. (32.2 and 37.8° C.).

21. The method of claim 1, wherein the partially attached particle is an artifact of the additive manufacturing process.
